(19) United States
(12) Patent Application Publication
(10) Pub. No.: US 2026/0282345 A1
(43) Pub. Date: Sep. 17, 2026

(54) PERIPHERAL MEMORY WORD LINE STRUCTURE

(71) Applicant: Samsung Electronics Co., Ltd., Suwon-si (KR)

(72) Inventors: JUNGMIN JU, Uiwang-si (KR); CHAN-SIC YOON, Anyang-si (KR); GYUHYUN KIL, Hwaseong-si (KR); Doosan BACK, Seoul (KR); JUNG-HOON HAN, Hwaseong-si (KR)

(21) Appl. No.: 19/676,428

(22) Filed: May 13, 2026

Related U.S. Application Data
(63) Continuation of application No. 17/862,987, filed on Jul. 12, 2022.

(30) Foreign Application Priority Data
Sep. 28, 2021 (KR) 10-2021-0127938

(51) Int. Cl. H10B 12/00; H10W 20/41; H10W 20/44; H10W 20/47

(52) U.S. Cl. CPC H10B 12/50; H10B 12/0335; H10B 12/09; H10B 12/315; H10B 12/488; H10W 20/425; H10W 20/435; H10W 20/4451; H10W 20/47

(57) ABSTRACT

A semiconductor device includes a peripheral word line on a substrate, a lower dielectric pattern covering the peripheral word line and including a first part covering a lateral surface of the peripheral word line and a second part covering a top surface of the peripheral word line, a contact plug penetrating the first part and the second part, and a filling pattern penetrating at least a portion of the second part. The contact plug includes a contact pad on a top surface of the lower dielectric pattern and a through plug penetrating the first and second parts. The filling pattern surrounds a lateral of the contact pad of the contact plug, the first part and the second part include the same material, the peripheral word line includes a metal-containing pattern, and the second part is in direct contact with a top surface of the metal-containing pattern.

### CROSS-REFERENCE TO RELATED APPLICATION

This U.S. nonprovisional application is a continuation of U.S. patent application Ser. No. 17/862,987 filed on Jul. 12, 2022, which claims priority under 35 U.S. C § 119 to Korean Patent Application No. 10-2021-0127938 filed on Sep. 28, 2021 in the Korean Intellectual Property Office, the disclosure of each of which is hereby incorporated by reference in its entirety.

### BACKGROUND

The present inventive concepts relate to a semiconductor device and a method of fabricating the same, and more particularly, to a semiconductor device including a lower dielectric pattern that covers a top surface of a peripheral word line and a method of fabricating the same.

Semiconductor devices have an important role in the electronic industry because of their small size, multi-functionality, and/or low fabrication cost. Semiconductor devices may be categorized as any one of semiconductor memory devices storing logic data, semiconductor logic devices processing operations of logic data, and hybrid semiconductor devices having both memory and logic elements.

Recently, high speed and low consumption of electronic products require that semiconductor devices embedded in the electronic products should have high operating speed and/or lower operating voltage. However, an increasing integration of semiconductor devices induces an increase in process difficulty and failure of semiconductor device production. As a result, an increase in higher integration of semiconductor devices may reduce production yields and properties of semiconductor devices. Therefore, various studies have been conducted for enhancing properties and production yields of semiconductor devices.

### SUMMARY

Some embodiments of the present inventive concepts provide a semiconductor device with increased reliability and improved electrical properties.

An object of the present inventive concepts is not limited to the mentioned above, and other objects which have not been mentioned above will be clearly understood to those skilled in the art from the following description.

According to some embodiments of the present inventive concepts, a semiconductor device may comprise: a substrate; a peripheral word line disposed on the substrate; a lower dielectric pattern disposed on the substrate and covering the peripheral word line, the lower dielectric pattern including a first part that covers a lateral surface of the peripheral word line and a second part that covers a top surface of the peripheral word line; a contact plug disposed on one side of the peripheral word line, the contact plug penetrating the first part and the second part of the lower dielectric pattern; and a filling pattern in contact with the second part of the lower dielectric pattern, the filling pattern penetrating at least a portion of the second part. The contact plug may include: a contact pad disposed on a top surface of the lower dielectric pattern; and a through plug that penetrates the first part and the second part of the lower dielectric pattern in a first direction perpendicular to a top surface of the substrate, the through plug being connected to the substrate. The filling pattern may surround a lateral surface of the contact pad. The first part and the second part of the lower dielectric pattern may include the same material.

According to some embodiments of the present inventive concepts, a method of fabricating a semiconductor device may comprise: forming a peripheral word line including a metal-containing pattern and a first lower capping pattern that are sequentially stacked on a substrate; forming a first part of a lower dielectric pattern, the first part of the lower dielectric pattern covering a lateral surface of the peripheral word line; forming a second part of the lower dielectric pattern, the second part of the lower dielectric pattern covering a top surface of the peripheral word line and a top surface of the first part of the lower dielectric pattern; forming a through hole that penetrates the first part and the second part of the lower dielectric pattern in a first direction perpendicular to a top surface of the substrate; and forming a contact plug including a through plug that fills the through hole and a contact plug on a top surface of the second part of the lower dielectric pattern. The first part and the second part of the lower dielectric pattern may be connected without a boundary therebetween and include the same material.

### BRIEF DESCRIPTION OF THE DRAWINGS

FIGS. 1 and 2 illustrate block diagrams showing a semiconductor device according to some embodiments of the present inventive concepts.

FIGS. 3 and 7 illustrate plan views respectively of sections P1 and P2 of FIGS. 1 and 2, showing a semiconductor device according to some embodiments of the present inventive concepts.

FIGS. 4 and 8 illustrate cross-sectional views taken along lines A-A′ and B-B′ of FIGS. 3 and 7, respectively.

FIGS. 5 and 6 illustrate cross-sectional views taken along A-A′ of FIG. 3, showing a semiconductor device according to some embodiments of the present inventive concepts.

FIGS. 9, 10, 11A to 16A, 17, and 18 illustrate cross-sectional views taken along line A-A′ of FIG. 3, showing a method of fabricating a semiconductor device according to some embodiments of the present inventive concepts.

FIGS. 11B to 16B illustrate cross-sectional views taken along line B-B′ of FIG. 7, showing a method of fabricating a semiconductor device according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts.

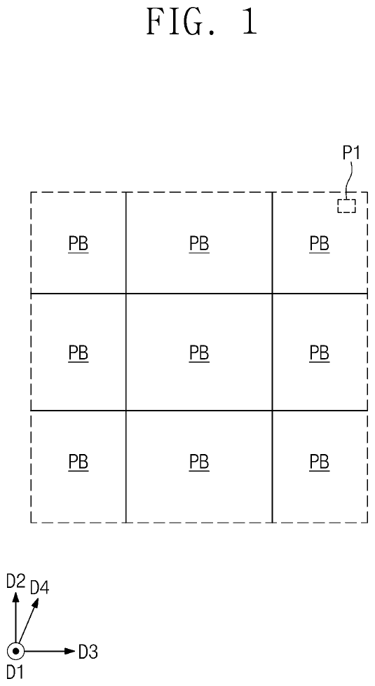

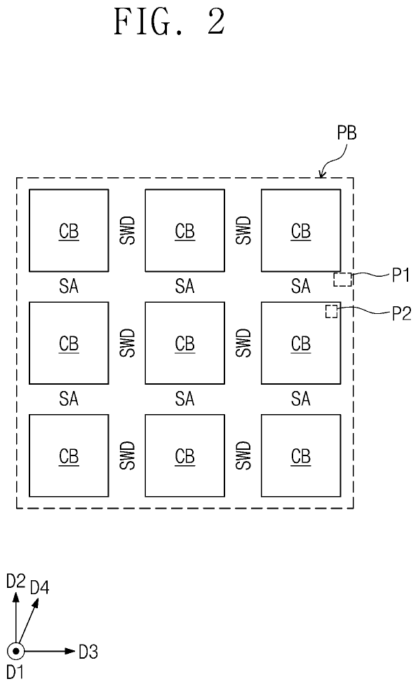

FIGS. 1 and 2 illustrate block diagrams showing a semiconductor device according to some embodiments of the present inventive concepts.

Referring to FIGS. 1 and 2, a semiconductor device may include a peripheral block PB. The semiconductor device may include a memory circuit, a logic circuit, or a combination thereof.

For example, as shown in FIG. 1, the semiconductor device may be a buffer die that includes peripheral blocks PB. A high bandwidth memory (HBM) chip may be constituted by the buffer die and memory devices that are stacked on the buffer die. Each of the peripheral blocks PB may include various logic circuits and peripheral circuits required for operation of the memory devices.

Alternatively, as shown in FIG. 2, the semiconductor device may include cell blocks CB, and a peripheral block PB between the cell blocks CB. The peripheral block PB may surround the cell blocks CB. The peripheral block PB may include sense amplifier circuits SA and sub-word line driver circuits SWD. The peripheral block PB may further include power and ground driver circuits for sense amplifier driving, but the present inventive concepts are not limited thereto.

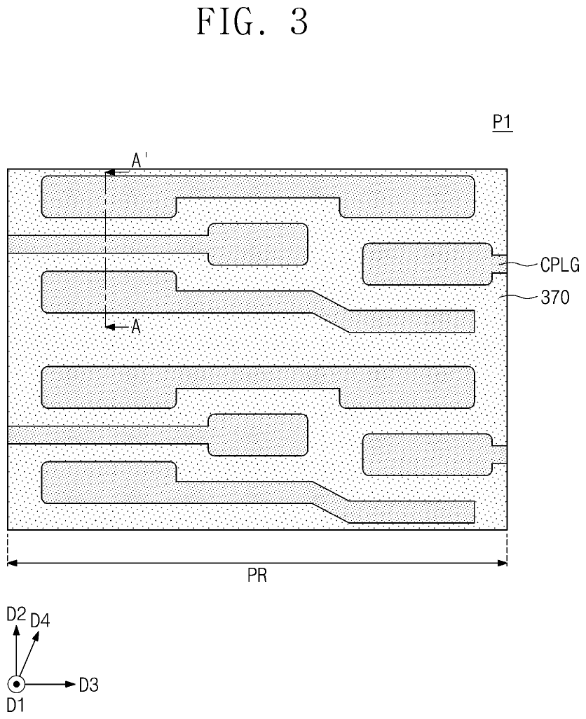

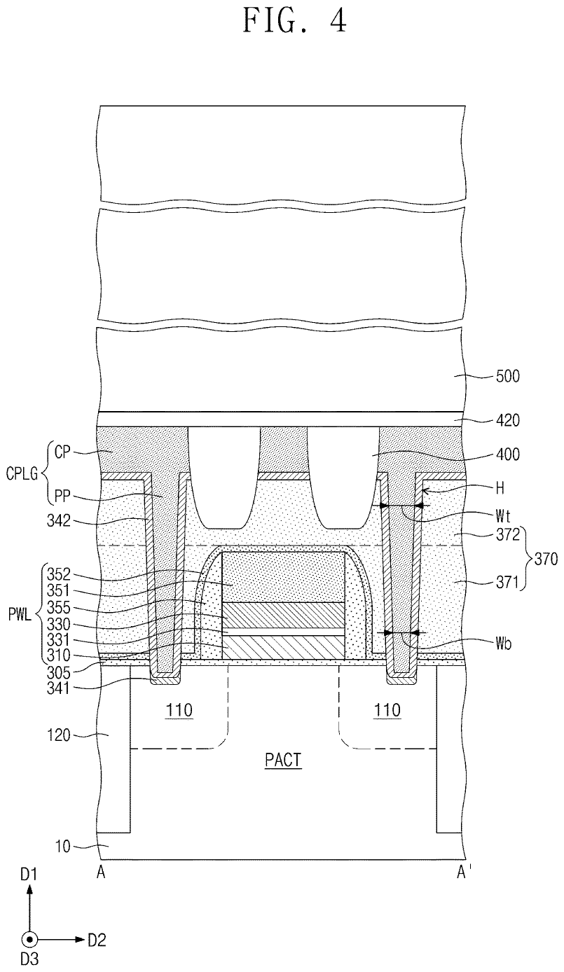

FIG. 3 illustrates a plan view of section P1 shown in FIGS. 1 and 2, showing a semiconductor device according to some embodiments of the present inventive concepts. FIGS. 4, 5, and 6 illustrate cross-sectional views taken along line A-A′ of FIG. 3, showing a semiconductor device according to some embodiments of the present inventive concepts.

Referring to FIGS. 3 and 4, a substrate 10 may be provided. The substrate 10 may be a semiconductor substrate, such as a silicon substrate, a germanium substrate, or a silicon-germanium substrate. The substrate 10 may include at its portion a peripheral region PR on which is provided the peripheral block PB of FIGS. 1 and 2.

A peripheral active pattern PACT may be disposed on the substrate 10. The peripheral active pattern PACT may be disposed on the peripheral region PR of the substrate 10. The peripheral active pattern PACT may be a portion of the substrate 10, which portion protrudes from the substrate 10 along a first direction D1 perpendicular to a top surface of the substrate 10.

Device isolation layers 120 may be disposed on opposite sides of the peripheral active pattern PACT. The device isolation layers 120 may be disposed in the substrate 10 to define the peripheral active pattern PACT. The device isolation layers 120 may include or may be formed of, for example, one or more of silicon oxide, silicon nitride, and silicon oxynitride.

Impurity sections 110 may be provided in the peripheral active pattern PACT. The impurity sections 110 may be provided in opposite edge areas of the peripheral active pattern PACT. The impurity sections 110 may include n-type or p-type impurities.

A gate dielectric pattern 305 and a peripheral word line PWL may be disposed on the peripheral active pattern PACT. The gate dielectric pattern 305 and the peripheral word line PWL may be sequentially stacked on the peripheral active pattern PACT. The gate dielectric pattern 305 may extend onto the device isolation layers 120. The gate dielectric pattern 305 may include or may be formed of, for example, silicon oxide.

The peripheral word line PWL may run across the peripheral active pattern PACT. The peripheral word line PWL may include a polysilicon pattern 310, a first ohmic pattern 331, a metal-containing pattern 330, a first lower capping pattern 351, a second lower capping pattern 352, and a spacer 355. The polysilicon pattern 310, the first ohmic pattern 331, the metal-containing pattern 330, and the first lower capping pattern 351 may be sequentially stacked on the gate dielectric pattern 305. The spacer 355 may be provided on a lateral surface of the polysilicon pattern 310, a lateral surface of the first ohmic pattern 331, a lateral surface of the metal-containing pattern 330, and a lateral surface of the first lower capping pattern 351. The second lower capping pattern 352 may cover a top surface of the first lower capping pattern 351 and may have a substantially uniform thickness extending along a lateral surface of the spacer 355 and a top surface of the gate dielectric pattern 305. A top surface of the peripheral word line PWL may include a top surface of the second lower capping pattern 352.

For example, the polysilicon pattern 310 may include impurity-doped polysilicon or impurity-undoped polysilicon. The first ohmic pattern 331 may include or may be formed of metal silicide. The metal-containing pattern 330 may include metal (e.g., tungsten, titanium, or tantalum). The first and second lower capping patterns 351 and 352 may include or may be formed of silicon nitride. The spacer 355 may include or may be formed of silicon oxide.

A lower dielectric pattern 370 may cover the peripheral word line PWL. The lower dielectric pattern 370 may include a first part 371 that covers a lateral surface of the peripheral word line PWL, and may also include on the first part 371 a second part 372 that covers the top surface of the peripheral word line PWL. The first part 371 may be a first portion of the lower dielectric pattern 370 and the second part 372 may be a second portion of the lower dielectric pattern 370. The first part 371 (i.e., the first portion of the lower dielectric pattern 370) is located at a height (or level) the same as or lower than that of the top surface of the peripheral word line PWL. The second part 372 (i.e., the second portion of the lower dielectric pattern 370) is located at a height (or level) higher than that of the top surface of the peripheral word line PWL.

The first and second parts 371 and 372 of the lower dielectric pattern 370 may include or may be formed of the same material. For example, the first and second parts 371 and 372 may include or may be formed of silicon oxide. As used herein, the “same material” may refer to materials having the same material composition. For example, the first and second parts 371 and 372 of the lower dielectric pattern 370 may be deemed to include or be formed of the same material when the first and second parts 371 and 372 of the lower dielectric pattern 370 have the same material composition (e.g., include or formed of the same material or set of materials and no other materials).

The second part 372 may further include a material different from that of the first part 371 or may include two or more kinds of material. For example, the first part 371 may include or may be formed of silicon oxide, and the second part 372 may include or may be formed of silicon oxide and an additional dielectric material other than silicon oxide. In this case, although not shown, the second part 372 may be formed of two or more dielectric layers.

The first and second parts 371 and 372 of the lower dielectric pattern 370 may be connected without a boundary therebetween. For example, as discussed below, the lower dielectric pattern 370 may continuously extend from a bottom surface of a contact pad CP to a lower portion of a through plug PP.

A contact plug CPLG may be disposed on one side of the peripheral word line PWL. Another contact plug CPLG may be disposed on another side of the peripheral word line PWL. The contact plug CPLG may include a material containing metal, such as tungsten.

The contact plug CPLG may include a contact pad CP and a through plug PP. The contact pad CP may be provided on a top surface of the lower dielectric pattern 370. The through plug PP may extend toward the substrate 10 from a bottom surface of the contact pad CP. The through plug PP may penetrate in the first direction D1 the first and second parts 371 and 372 of the lower dielectric pattern 370 and may connect with the substrate 10. The lower dielectric pattern 370 may continuously extend from the bottom surface of the contact pad CP to a lower portion of the through plug PP.

The contact pad CP may be provided on and connected to the through plug PP. The contact pad CP may have widths in second and third directions D2 and D3 that are parallel to the top surface of the substrate 10 while intersecting each other (or being orthogonal to each other), and the widths of the contact pad CP may be greater than widths in the second and third directions D2 and D3 of the through plug PP. When viewed in plan, an area on which the contact pad CP is provided may include an area on which the through plug PP is provided.

The through plug PP may have a width in the second direction D2 or the third direction D3. The through plug PP may have a width Wt at its upper portion the same as or greater than a width Wb at its lower portion. For example, the width of the through plug PP may increase in the first direction D1 from the lower portion toward the upper portion of the through plug PP.

The second part 372 of the lower dielectric pattern 370 and the contact pad CP may be sequentially stacked on the peripheral word line PWL. For example, the second part 372 may be interposed between the bottom surface of the contact pad CP and the top surface of the peripheral word line PWL. The second part 372 may surround the upper portion of the through plug PP.

A diffusion stop pattern 342 may be provided on a portion of the contact plug CPLG. For example, the diffusion stop pattern 342 may cover the bottom surface of the contact pad CP, lateral and bottom surfaces of the through plug PP, and may surround the contact plug CPLG. The diffusion stop pattern 342 on the bottom surface of the contact pad CP may be in contact with a top surface of the second part 372 of the lower dielectric pattern 370 and may be interposed between the contact pad CP and the second part 372. The diffusion stop pattern 342 on the lateral surfaces of the contact plug CPLG may come into contact with the first part 371 of the lower dielectric pattern 370 and the second part 372 of the lower dielectric pattern 370. Portions of the first part 371 of the lower dielectric pattern 370 may be disposed between the diffusion stop pattern 342 and the second lower capping pattern 352. For example, portions of the first part 371 of the lower dielectric pattern 370 may be in contact with the diffusion stop pattern 342 and the second lower capping pattern 352. The diffusion stop pattern 342 may include or may be formed of metal nitride, such as titanium nitride or tantalum nitride.

A filling pattern 400 may surround a lateral surface of the contact pad CP of the contact plug CPLG. The filling pattern 400 may be interposed between the contact plug CPLG (e.g., a first contact plug CPLG) and another immediately adjacent contact plug CPLG (e.g., a second contact plug CPLG). A portion of the filling pattern 400 may extend into the second part 372 of the lower dielectric pattern 370. The portion of the filling pattern 400 may penetrate at least a portion of the second part 372. For example, the filling pattern 400 may have a bottom surface in contact with the lower dielectric pattern 370. For another example, although not shown, the filling pattern 400 may have a bottom surface in contact with the top surface of the peripheral word line PWL. In addition, portions of the second part 372 of the lower dielectric pattern 370 may be disposed between the diffusion stop pattern 342 and the filling pattern 400. For example, portions of the second part 372 of the lower dielectric pattern 370 may be in contact with the diffusion stop pattern 342 and the filling pattern 400. The filling pattern 400 may include or may be formed of silicon nitride and may be formed of a single or multiple layer. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

An etch stop pattern 420 may cover the filling pattern 400 and the contact pad CP. The etch stop pattern 420 may include or may be formed of, for example, SiBN. The etch stop pattern 420 may have a single or multiple layer.

An upper dielectric pattern 500 may be provided on the etch stop pattern 420. The upper dielectric pattern 500 may include or may be formed of, for example, silicon oxide. Although not shown, a metal contact may be provided in the upper dielectric pattern 500. The metal pattern may penetrate, in the first direction D1, the upper dielectric pattern 500 and the etch stop pattern 420, and may connect with the contact plug CPLG.

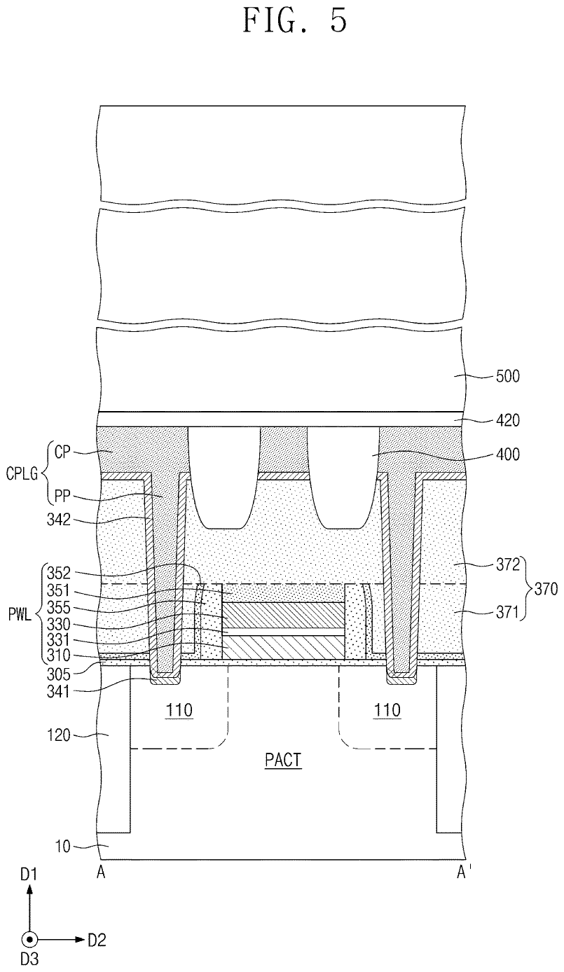

Referring to FIG. 5, in some embodiments, the top surface of the peripheral word line PWL may include a top surface of the first lower capping pattern 351. The second part 372 of the lower dielectric pattern 370 may cover (e.g., directly cover by contacting) the top surface of the first lower capping pattern 351. Separated second lower capping patterns 352 may be provided, and the plurality of second lower capping patterns 352 may not cover the top surface of the first lower capping pattern 351. The second lower capping patterns 352 may be provided on opposite sides of the first lower capping pattern 351. The top surfaces of the second lower capping patterns 352 may be covered with the second part 372.

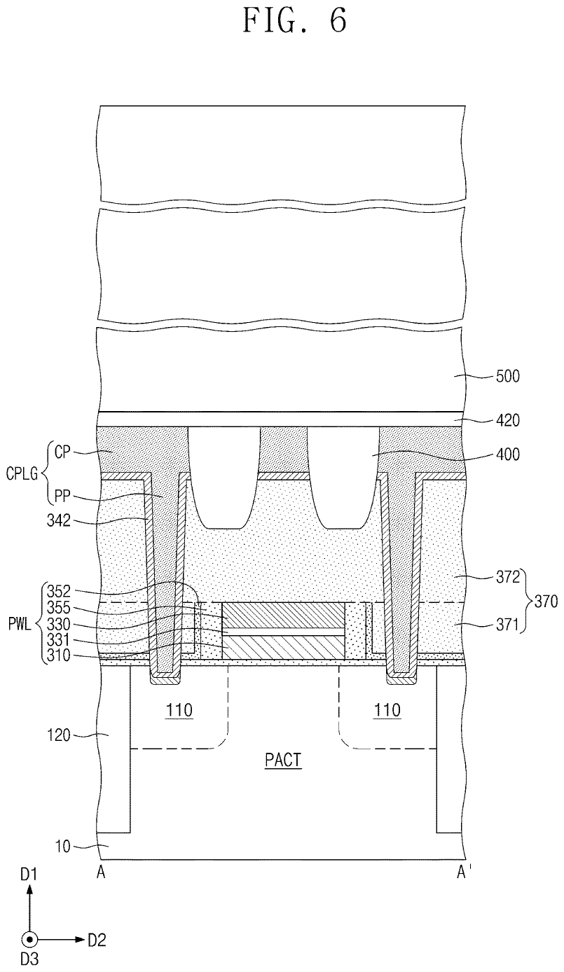

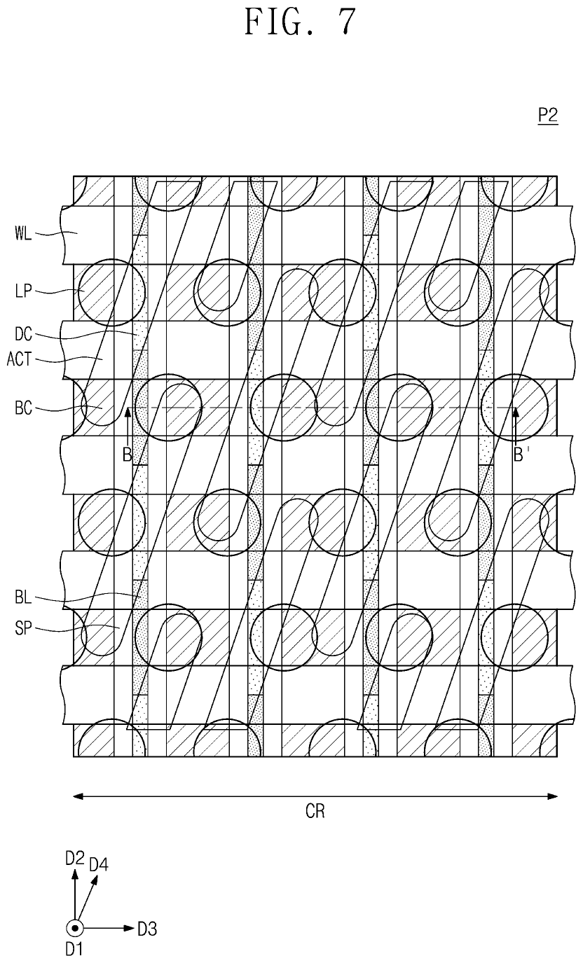

Referring to FIG. 6, in some embodiments, the top surface of the peripheral word line PWL may include a top surface of the metal-containing pattern 330. The second part 372 of the lower dielectric pattern 370 may cover and contact the top surface of the metal-containing pattern 330.

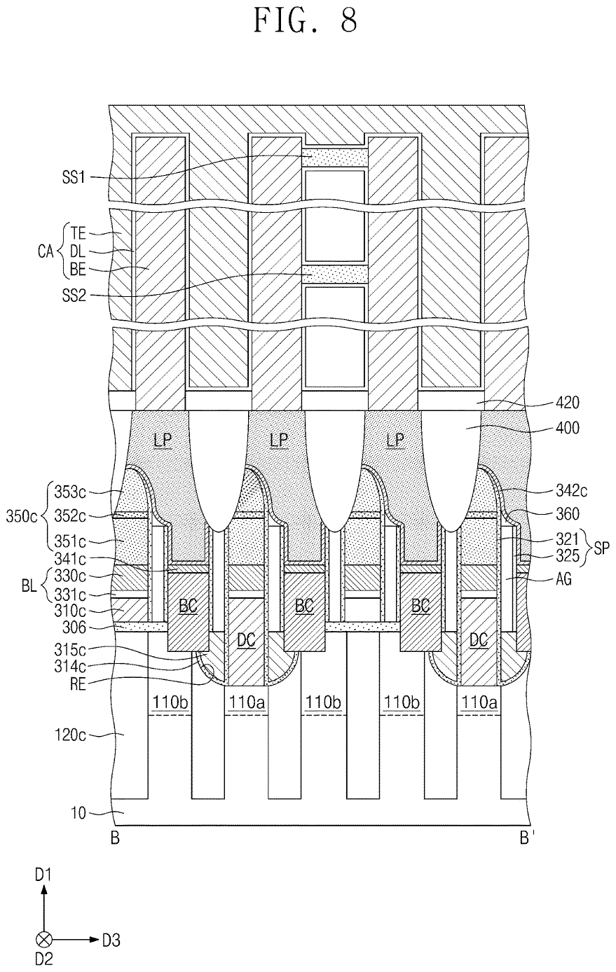

FIG. 7 illustrates a plan view of section P2 shown in FIG. 2, showing a semiconductor device according to some embodiments of the present inventive concepts. FIG. 8 illustrates a cross-sectional view taken along line B-B′ of FIG. 7. With reference to FIGS. 7 and 8, the following will describe a semiconductor device provided with a cell region CR.

Referring to FIGS. 7 and 8, the substrate 10 may further include a cell region CR. The substrate 10 may include the cell region CR at its area where the cell blocks CB of FIG. 2 are provided.

Cell active patterns ACT may be disposed on the cell region CR of the substrate 10. When viewed in plan, the cell active patterns ACT may be spaced apart from each other in the second direction D2 and the third direction D3. The cell active patterns ACT may have a bar shape that extends in a fourth direction D4 that is parallel to the top surface of the substrate 10 and intersects the second and third directions D2 and D3.

Cell device isolation layers 120c may be disposed between the cell active patterns ACT on the cell region CR. The cell device isolation layers 120c may be disposed in the substrate 10 to define the cell active patterns ACT.

The cell region CR may be provided thereon with word lines WL that run across the cell active patterns ACT and the cell device isolation layers 120c. The word lines WL may be disposed in grooves formed in the cell active patterns ACT and the cell device isolation layers 120c. The word lines WL may be spaced apart from each other along the second direction D2 while extending in the third direction D3. The word lines WL may be buried in the substrate 10.

First and second impurity sections 110a and 110b may be provided in the cell active patterns ACT. Each of the first impurity sections 110a may be provided between a pair of word lines WL that run across the cell active patterns ACT. The second impurity sections 110b may be provided on opposite edge areas of each of the cell active patterns ACT. The first impurity sections 110a may include impurities whose conductivity type is the same as that of the second impurity sections 110b.

The substrate 10 may be provided thereon with a buffer pattern 306 that covers the cell active patterns ACT, the cell device isolation layers 120c, and the word lines WL. The buffer pattern 306 may include or may be formed of, for example, one or more of silicon oxide, silicon nitride, and silicon oxynitride.

Bit lines BL may be disposed on the buffer pattern 306. The bit lines BL may extend in the second direction D2 and may be spaced apart from each other in the third direction D3. Each of the bit lines BL may include a first cell ohmic pattern 331c and a cell metal-containing pattern 330c that are sequentially stacked. The first cell ohmic pattern 331c and the cell metal-containing pattern 330c may include or may be formed of the same materials as those of the first ohmic pattern 331 and the metal-containing pattern 330 of FIG. 4, respectively.

Cell polysilicon patterns 310c may be interposed between the bit lines BL and the buffer pattern 306. The cell polysilicon patterns 310c may include or may be formed of the same material as that of the polysilicon pattern 310 of FIG. 4.

Bit-line contacts DC may be correspondingly interposed between the bit lines BL and the first impurity sections 110a. The bit lines BL may be electrically connected through the bit-line contacts DC to the first impurity sections 110a. The bit-line contacts DC may include impurity-doped polysilicon or impurity-undoped polysilicon.

The bit-line contacts DC may be disposed in recesses RE. The recess RE may be provided on upper portions of the first impurity sections 110a and upper portions of adjacent cell device isolation layers 120c. A first buried dielectric pattern 314c and a second buried dielectric pattern 315c may fill an occupied portion of the recess RE.

A cell capping pattern 350c may extend in the second direction D2 on each of the bit lines BL. The cell capping pattern 350c may include a first cell capping pattern 351c, a second cell capping pattern 352c, and an upper cell capping pattern 353c that are sequentially stacked and extend in the second direction D2. The second part 372 of the lower dielectric pattern 370 shown in FIG. 4 may include or may be formed of a material whose dielectric constant is less than that of the upper cell capping pattern 353c. For example, the upper cell capping pattern 353c may be formed of silicon nitride, and the second part 372 may include or may be formed of silicon oxide whose dielectric constant is less than that of silicon nitride.

A bit-line spacer SP may cover a lateral surface of the cell polysilicon pattern 310c, an upper lateral surface of the bit-line contact DC, a lateral surface of the bit line BL, and a lateral surface of the cell capping pattern 350c. The bit-line spacer SP may extend along the first direction D1 on each of the bit lines BL.

The bit-line spacer SP may include a first sub-spacer 321 and a second sub-spacer 325 that are spaced apart from each other. For example, an air gap AG may separate the first sub-spacer 321 from the second sub-spacer 325. The first sub-spacer 321 may be in contact with the lateral surface of the bit line BL while extending onto the lateral surface of the cell capping pattern 350c. The second sub-spacer 325 may be provided along a lateral surface of the first sub-spacer 321. The first and second sub-spacers 321 and 325 may include or may be formed of silicon nitride.

An upper spacer 360 may cover the lateral surface of the first sub-spacer 321 and may extend onto a top surface of the second sub-spacer 325. The upper spacer 360 may further cover the air gap AG.

Storage node contacts BC may be interposed between neighboring ones of the bit lines BL. The storage node contacts BC may be spaced apart from each other in the second direction D2 and the third direction D3. The storage node contacts BC may include impurity-doped polysilicon or impurity-undoped polysilicon.

A second cell ohmic pattern 341c may be disposed on each of the storage node contacts BC. The second cell ohmic pattern 341c may include or may be formed of the same material as that of the second ohmic pattern 341 shown in FIG. 4.

A cell diffusion stop pattern 342c may be formed to conformally cover the second cell ohmic pattern 341c, the bit-line spacer SP, and the cell capping pattern 350c. The cell diffusion stop pattern 342c may include or may be formed of the same material as that of the diffusion stop pattern 342 shown in FIG. 4. The second cell ohmic pattern 341c may be interposed between the cell diffusion stop pattern 342c and each of the storage node contacts BC.

Landing pads LP may be correspondingly disposed on the storage node contacts BC. The landing pads LP may be spaced apart from each other in the second direction D2 and the third direction D3. The landing pads LP may include or may be formed of a material containing metal, such as tungsten.

A filling pattern 400 may surround each of the landing pads LP. The filling pattern 400 may be interposed between neighboring landing pads LP.

Bottom electrodes BE may be disposed on corresponding landing pads LP. The bottom electrodes BE may include at least one selected from impurity-doped polysilicon, metal nitride such as titanium nitride, and metal such as tungsten, aluminum, or copper. Each of the bottom electrodes BE may have a circular pillar shape, a hollow cylindrical shape, or a cup shape. An upper support pattern SS1 may support upper sidewalls of the bottom electrodes BE, and a lower support pattern SS2 may support lower sidewalls of the bottom electrodes BE. The upper and lower support patterns SS1 and SS2 may include or may be formed of a dielectric material, such as silicon nitride, silicon oxide, or silicon oxynitride.

An etch stop pattern 420 may be provided on the filling pattern 400 between the bottom electrodes BE. A dielectric layer DL may cover surfaces of the bottom electrodes BE and surfaces of the upper and lower support patterns SS1 and SS2. The dielectric layer DL may include or may be formed of, for example, at least one selected from silicon oxide, silicon nitride, silicon oxynitride, and high-k dielectrics (e.g., hafnium oxide). A top electrode TE may be disposed on the dielectric layer DL and may fill a space between the bottom electrodes BE. The top electrode TE may include or may be formed of at least one selected from an impurity-doped polysilicon layer, an impurity-doped silicon-germanium layer, a metal nitride layer such as a titanium nitride layer, and a metal layer such as a tungsten layer, an aluminum layer, or a copper layer. The bottom electrodes BE, the dielectric layer DL, and the top electrode TE may constitute a capacitor CA.

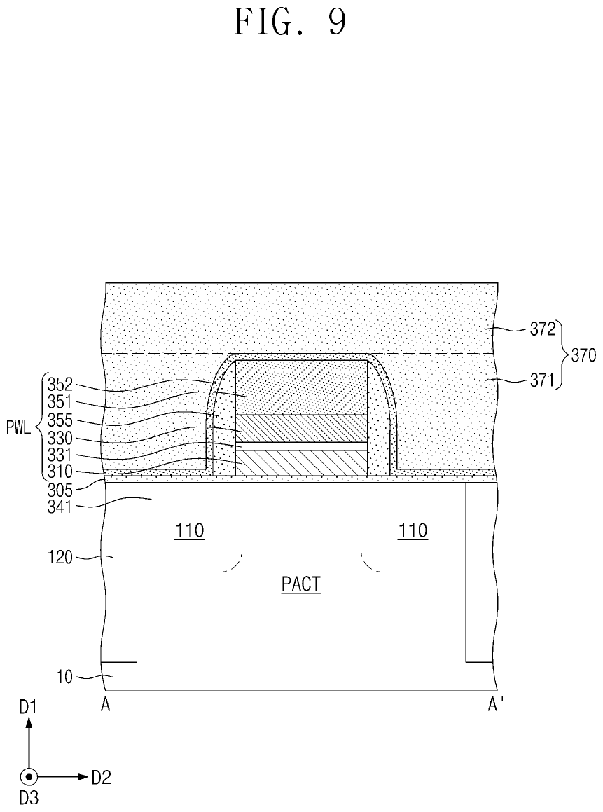

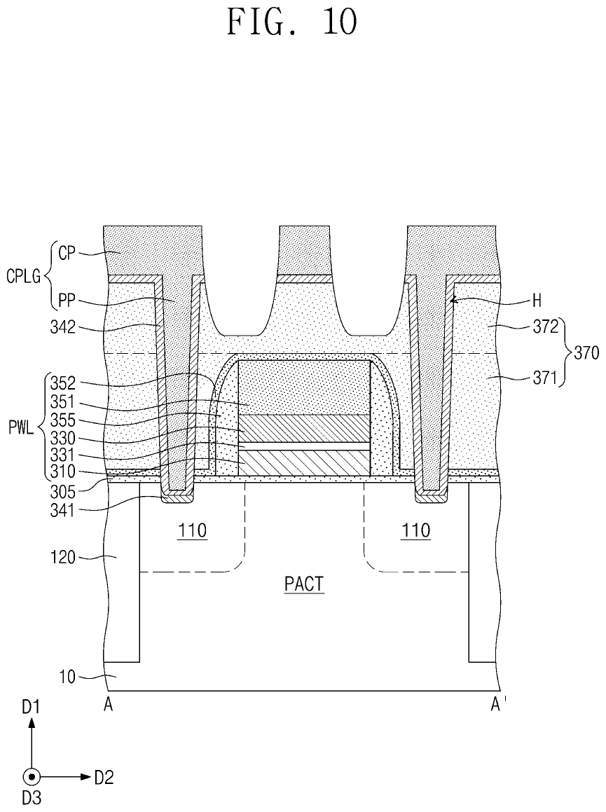

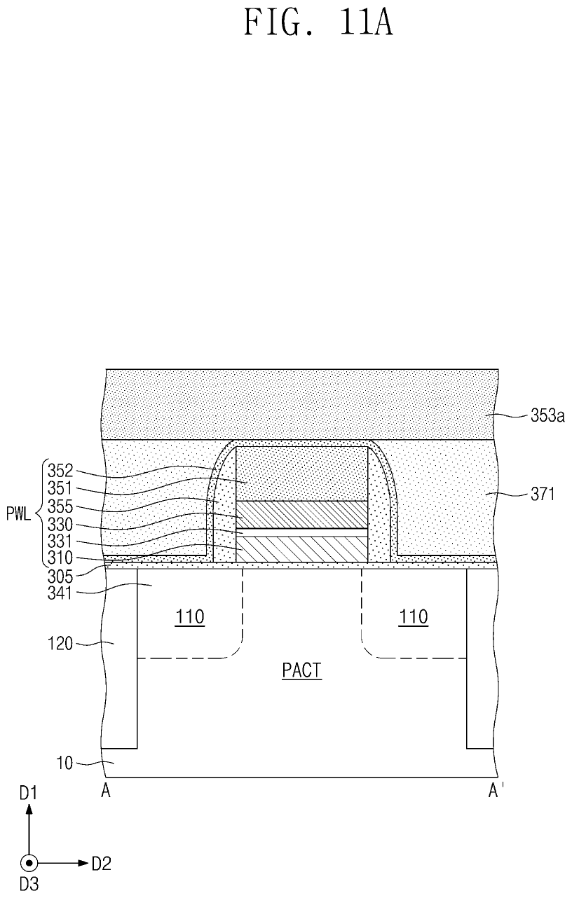

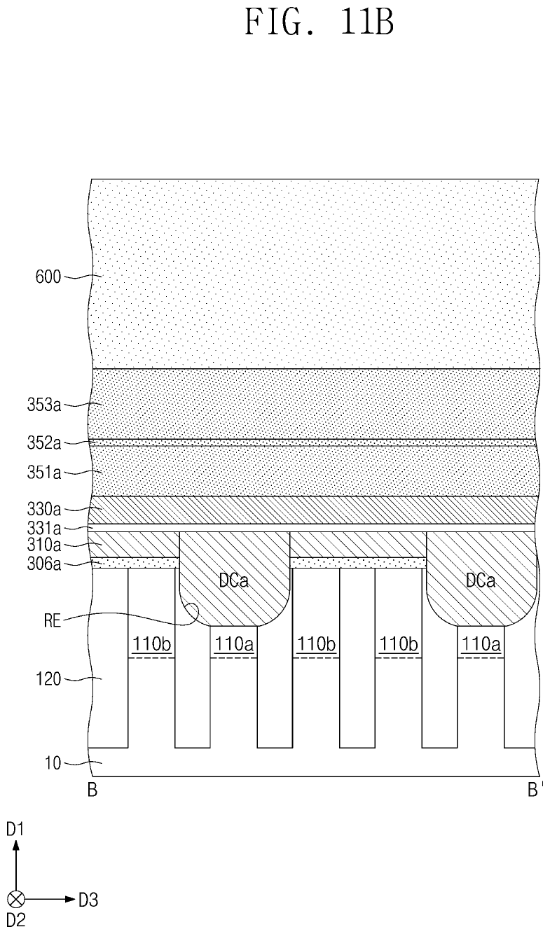

FIGS. 9 and 10 illustrate cross-sectional views taken along line A-A′ of FIG. 3, showing a method of fabricating a semiconductor device according to some embodiments of the present inventive concepts. The following will describe a method of fabricating a semiconductor device according to some embodiments of the present inventive concepts. A duplicate explanation will be omitted for brevity of description.

Referring to FIG. 9, a peripheral active pattern PACT and device isolation layers 120 may be formed on a peripheral region PR of a substrate 10. Impurity sections 110 may be formed in the peripheral active pattern PACT. A gate dielectric pattern 305 may be formed on the peripheral active pattern PACT and the device isolation layers 120.

A peripheral word line PWL may be formed on the peripheral active pattern PACT. The peripheral word line PWL may include a polysilicon pattern 310, a first ohmic pattern 331, a metal-containing pattern 330, a first lower capping pattern 351, a second lower capping pattern 352, and a spacer 355. The polysilicon pattern 310, the first ohmic pattern 331, the metal-containing pattern 330, and the first lower capping pattern 351 may be formed sequentially stacked on the gate dielectric pattern 305. The second lower capping pattern 352 may cover a top surface of the first lower capping pattern 351 and may have a substantially uniform thickness extending along a lateral surface of the spacer 355 and a top surface of the gate dielectric pattern 305.

A lower dielectric pattern 370 may be formed to cover the peripheral word line PWL. The lower dielectric pattern 370 may include a first part 371 that covers a lateral surface of the peripheral word line PWL, and may also include on the first part 371 a second part 372 that covers a top surface of the peripheral word line PWL. The first part 371 and the second part 372 may be connected without a boundary therebetween and may include or may be formed of the same material. For example, the first and second parts 371 and 372 may include or may be formed of silicon oxide.

The formation of the lower dielectric pattern 370 may include, for example, forming the first part 371 of the lower dielectric pattern 370 to cover the lateral surface of the peripheral word line PWL and forming the second part 372 of the lower dielectric pattern 370 to cover the top surface of the peripheral word line PWL and a top surface of the first part 371.

Alternatively, the formation of the lower dielectric pattern 370 may include simultaneously forming the first part 371 and the second part 372 of the lower dielectric pattern 370.

Referring to FIG. 10, a through hole H may be formed to penetrate the first and second parts 371 and 372 of the lower dielectric pattern 370 in a first direction D1 perpendicular to a top surface of the substrate 10. The through hole H may be formed by an etching process and may extend in the first direction D1 to expose a portion of the substrate 10. The portion of the substrate 10 may be an area in the impurity section 110. The through hole H may be disposed on one side of the peripheral word line PWL.

A contact plug CPLG may be formed to fill the through hole H. The contact plug CPLG may include a through plug PP that fills the through hole H and a contact pad CP on a top surface of the second part 372 of the lower dielectric pattern 370.

The formation of the contact plug CPLG may include forming a contact layer to fill the through hole H and to cover the second part 372 of the lower dielectric pattern 370, and performing an etching process to divide the contact layer into contact plugs CPLG. In this procedure, a second ohmic pattern 341 may be formed between the through plug PP and the portion of the substrate 10, and forming a diffusion stop pattern 342 to surround the through plug PP and to intervene between the second part 372 and a bottom surface of the contact pad CP.

Referring back to FIG. 4, a filling pattern may fill an empty space that is formed by etching the contact layer. The filling pattern 400 may be formed between neighboring (i.e., adjacent) contact plugs CPLG.

An etch stop pattern 420 may be formed to cover the filling pattern 400 and the contact pad CP. An upper dielectric pattern 500 may be provided on the etch stop pattern 420. Although not shown, a metal contact may be formed in the upper dielectric pattern 500. The metal contact may be formed to penetrate, in the first direction D1, the upper dielectric pattern 500 and the etch stop pattern 420, and may be formed to connect with the contact plug CPLG.

FIGS. 11A to 16A illustrate cross-sectional views taken along line A-A′ of FIG. 3, showing a method of fabricating a semiconductor device according to some embodiments of the present inventive concepts. FIGS. 11B to 16B illustrate cross-sectional views taken along line B-B′ of FIG. 7, showing a method of fabricating a semiconductor device according to some embodiments of the present inventive concepts. The following will discuss a method of fabricating a semiconductor device including a cell region CR. A duplicate explanation will be omitted for brevity of description.

Referring to FIGS. 11A and 11B, a substrate 10 may be provided which includes a cell region CR and a peripheral region PR. On the peripheral region PR, a peripheral word line PWL may be formed, and a first part 371 may be formed to cover a lateral surface of the peripheral word line PWL.

On the cell region CR, cell active patterns ACT and a cell device isolation layer 120c may be formed in the substrate 10, and first and second impurity sections 110a and 110b may be formed in the cell active patterns ACT. Afterwards, a buffer layer 306a and a cell polysilicon layer 310a may be sequentially stacked, and on the first impurity sections 110a, a recess RE may be formed by etching the cell polysilicon layer 310a, the buffer layer 306a, the first impurity section 110a, and a portion of the cell device isolation layer 120. A preliminary bit-line contact DCa may be formed to fill the recess RE, and thereafter, a cell ohmic layer 331a, a cell metal-containing layer 330a, a first cell capping layer 351a, and a second cell capping layer 352a may be sequentially stacked. A top surface of the second cell capping layer 352a may be located at a height (or level) substantially the same as that of a top surface of the second lower capping pattern 352 of the peripheral word line PWL.

An upper capping layer 353a may be formed on the peripheral region PR and the cell region CR. The upper capping layer 353a may cover the first part 371 and the peripheral word line PWL on the peripheral region PR, and may also cover the second cell capping layer 352a on the cell region CR. The upper capping layer 353a may include or may be formed of silicon nitride.

A photoresist pattern 600 may be formed on the upper capping layer 353a on the cell region CR. The formation of the photoresist pattern 600 may include forming a photoresist layer, and performing exposure and development processes on the photoresist layer. The photoresist pattern 600 may not be formed on the peripheral region PR.

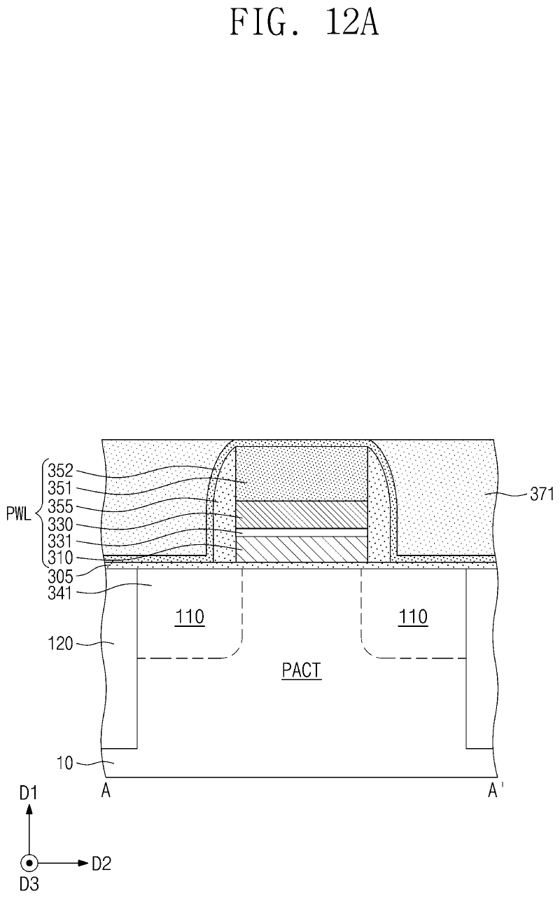

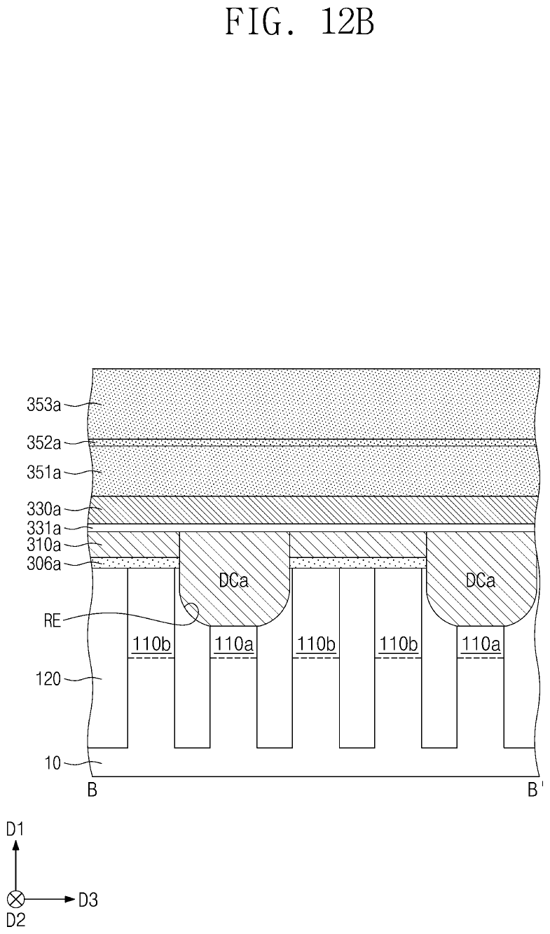

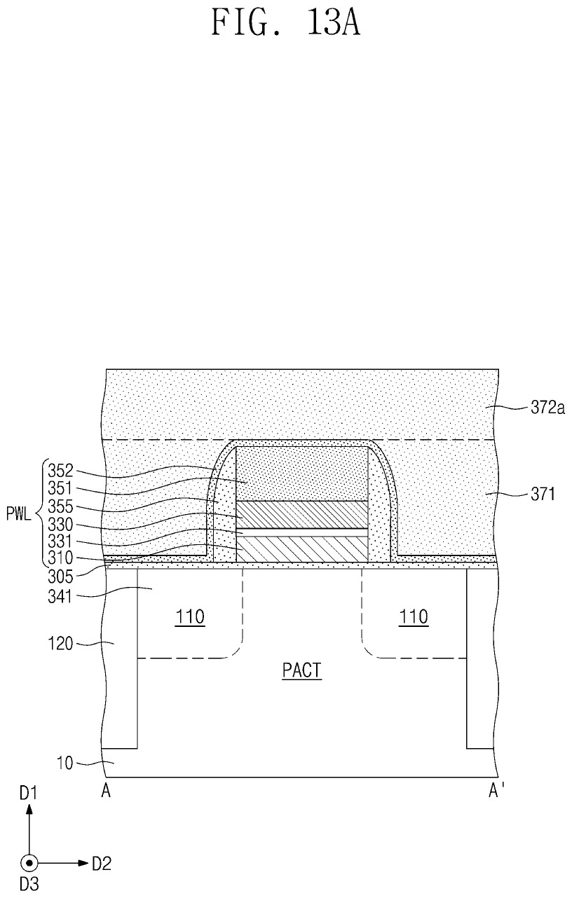

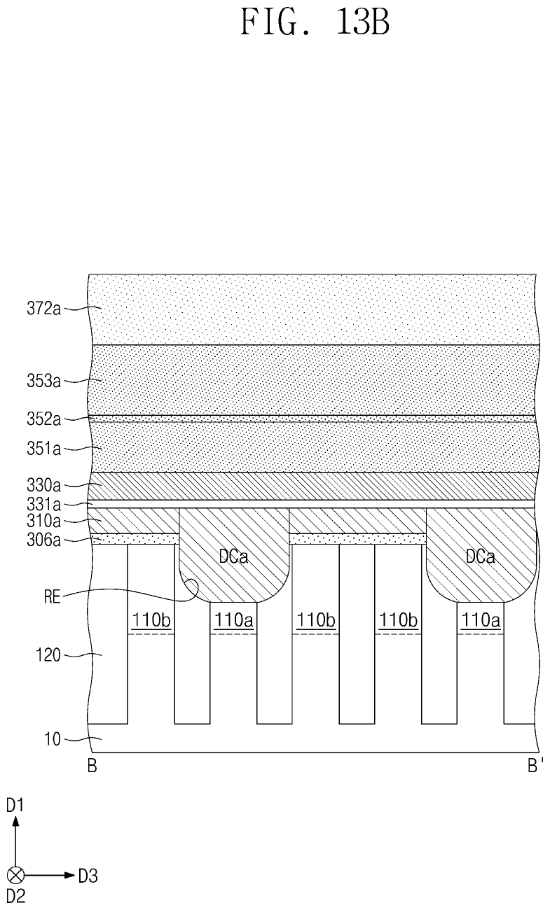

Referring to FIGS. 12A and 12B, on the peripheral region PR, the upper capping layer 353a which is exposed (i.e., not covered) by the photoresist pattern 600 may be removed. The removal of the upper capping layer 353a on the peripheral region PR may include etching the upper capping layer 353a on the peripheral region PR. The etching process may expose a top surface of the first part 371. After that, the photoresist pattern 600 may be removed from the cell region CR.

Referring to FIGS. 13A and 13B, a preliminary layer 372a may be formed on the cell region CR and the peripheral region PR. The preliminary layer 372a may cover the top surface of the first part 371 on the peripheral region PR, and may also cover a top surface of the upper capping layer 353a on the cell region CR.

On the peripheral region PR, the preliminary layer 372a may be in contact with and connected to the first part 371 without a boundary therebetween. The preliminary layer 372a may include or may be formed of the same material as that of the first part 371. For example, the preliminary layer 372a and the first part 371 may include or may be formed of silicon oxide. The preliminary layer 372a may include or may be formed of a material whose dielectric constant is less than that of the upper capping layer 353a.

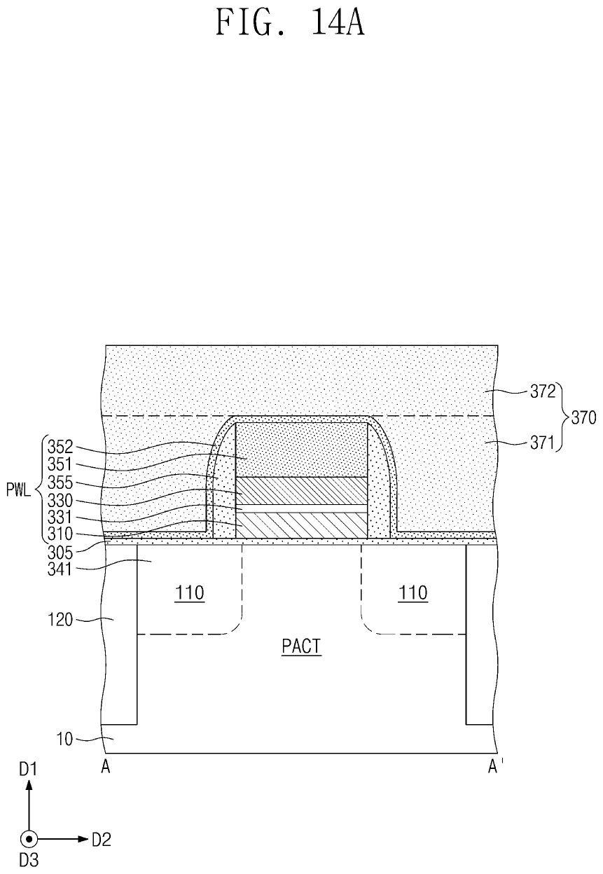

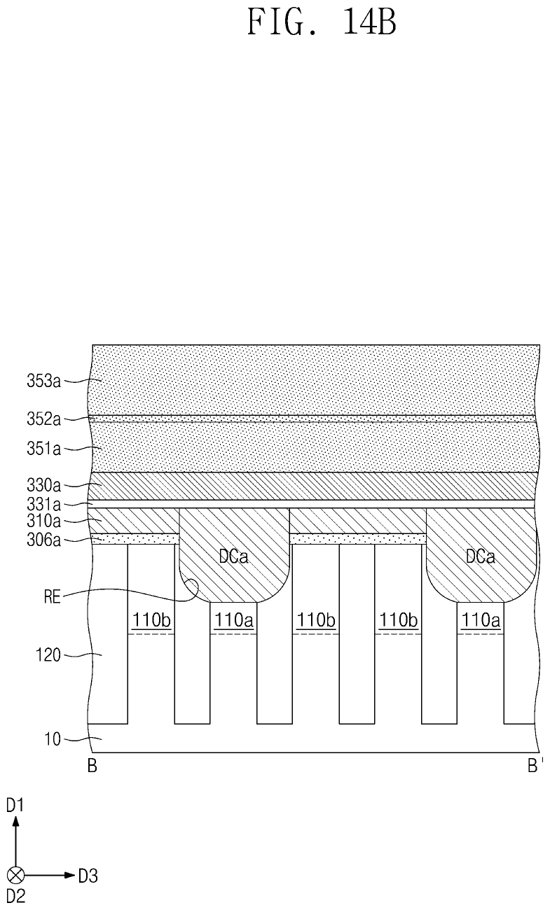

Referring to FIGS. 14A and 14B, the preliminary layer 372a may be removed from the cell region CR. The removal of the preliminary layer 372a may include performing a planarization process (e.g., CMP) on the preliminary layer 372a. The removal of the preliminary layer 372a may expose the top surface of the upper capping layer 353a on the cell region CR.

On the peripheral region PR, the preliminary layer 372a may be formed into a second part 372. The second part 372 and the first part 371 may constitute a lower dielectric pattern 370. For example, the second part 372 may have a top surface located at a height (or level) substantially the same as that of the top surface of the upper capping layer 353a. For another example, the second part 372 may have a top surface located at a height (or level) different from that of the top surface of the upper capping layer 353a. In this case, the top surface of the second part 372 may be located at a height (or level) lower or higher than that of the top surface of the upper capping layer 353a.

Referring back to FIGS. 4 and 8, on the cell region CR, bit-line contacts DC, cell polysilicon patterns 310c,

bit lines BL, and cell capping patterns 350c may be formed by etching the preliminary bit-line contacts DCa, the cell polysilicon layer 310a, the cell ohmic layer 331a, the cell metal-containing layer 330a, the first cell capping layer 351a, the second cell capping layer 352a, and the upper capping layer 353a that are shown in FIG. 14B. Bit-line spacers SP may be formed to cover the cell capping patterns 350c and lateral surfaces of the bit lines BL. In this procedure, a first buried dielectric pattern 314c and a second buried dielectric pattern 315c may be formed to fill an occupied portion of the recess RE.

Storage node contacts BC may be formed to interpose between the bit lines BL. In this case, an upper spacer 360 may be formed on top surfaces of the bit-line spacers SP.

Afterwards, on the peripheral region PR, a through hole H may be formed by an etching process, and a contact layer may be formed to fill the through hole H and to cover the second part 372. At the same time, on the cell region CR, the contact layer may cover the storage node contacts BC and the cell capping patterns 350c. Therefore, a second ohmic pattern 341 and a diffusion stop pattern 342 may be formed on the peripheral region PR, and a second cell ohmic pattern 341c and a cell diffusion stop pattern 342c may be formed on the cell region CR.

An etching process may be performed on the contact layer. The etching process may be executed such that the contact layer may be separated into contact plugs CPLG on the peripheral region PR and into landing pads LP on the cell region CR. A filling pattern 400 may be formed to fill a space between neighboring (i.e., adjacent) contact plugs CPLG and a space between the neighboring landing pads LP.

An etch stop pattern 420 may be formed on the filling pattern 400. On the peripheral region PR, the etch stop pattern 420 may extend onto a top surface of the contact plug CPLG.

On the cell region CR, bottom electrodes BE may be formed on corresponding landing pads LP. An upper support pattern SS1 may be formed on upper sidewalls of the bottom electrodes BE, and a lower support pattern SS2 may be formed on lower sidewalls of the bottom electrodes BE. A dielectric layer DL may be formed to cover surfaces of the bottom electrodes BE and surfaces of the upper and lower support patterns SS1 and SS2, and a top electrode TE may be formed on the dielectric layer DL to fill a space between the bottom electrodes BE. The bottom electrodes BE, the dielectric layer DL, and the top electrode TE may constitute a capacitor CA.

On the peripheral region PR, an upper dielectric pattern 500 may be formed on the filling pattern 400 and the contact plug CPLG. The upper dielectric pattern 500 may cover the filling pattern 400 and the contact plug CPLG.

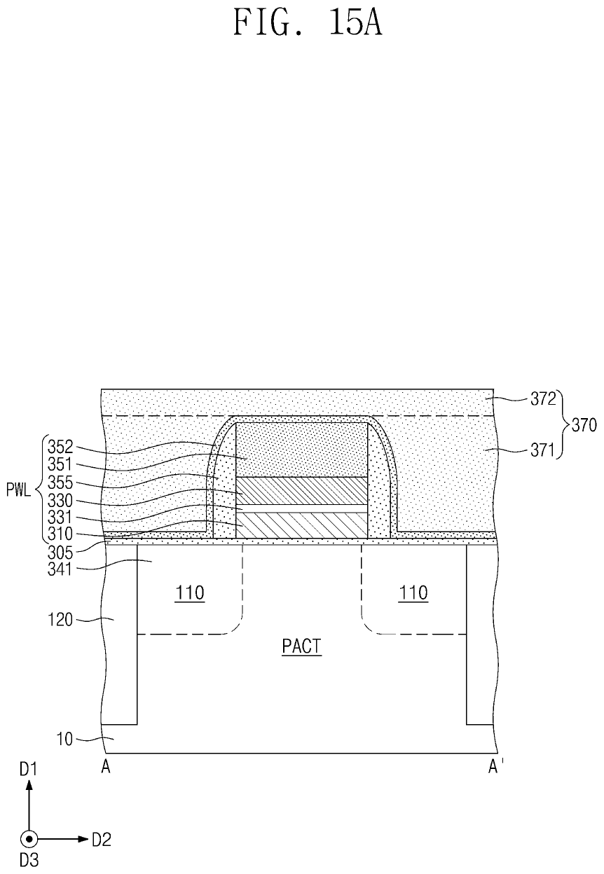

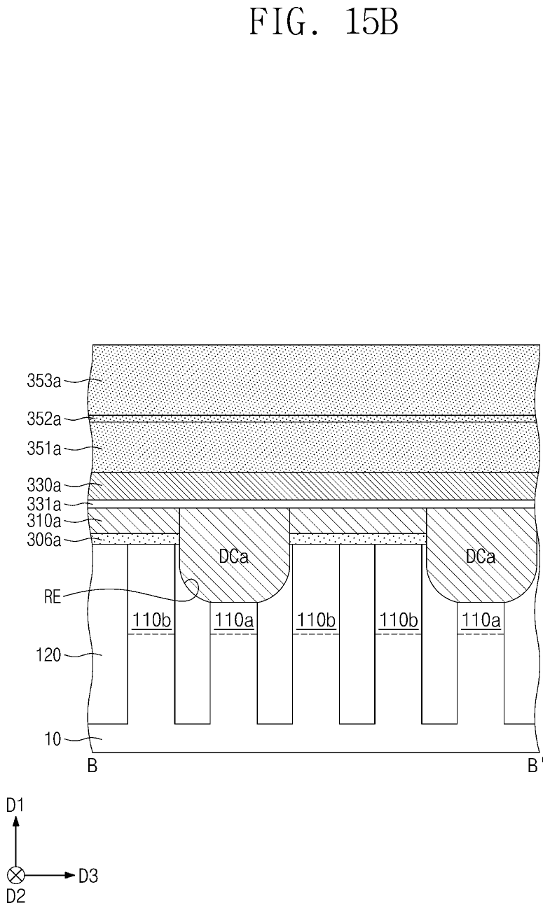

FIGS. 15A and 15B illustrate cross-sectional views respectively taken along lines A-A′ and B-B′ of FIGS. 3 and 7, showing a method of fabricating a semiconductor device according to some embodiments of the present inventive concepts.

Referring to FIGS. 15A and 15B, after the removal of the preliminary layer 372a on the cell region CR, an upper portion of the preliminary layer 372a may further be partially removed from the peripheral region PR. For example, the removal process may include an etching process. A non-removed portion of the preliminary layer 372a may constitute the second part 372 of the lower dielectric pattern 370 in the peripheral region PR.

The upper capping layer 353a on the cell region CR may not be removed during the removal process. After the removal process, the second part 372 on the peripheral region PR may have a top surface lower than that of the upper capping layer 353a on the cell region CR. A step difference between the top surface of the second part 372 and the top surface of the upper capping layer 353a may be adjusted by using an etch selectivity between the second part 372 and the upper capping layer 353a.

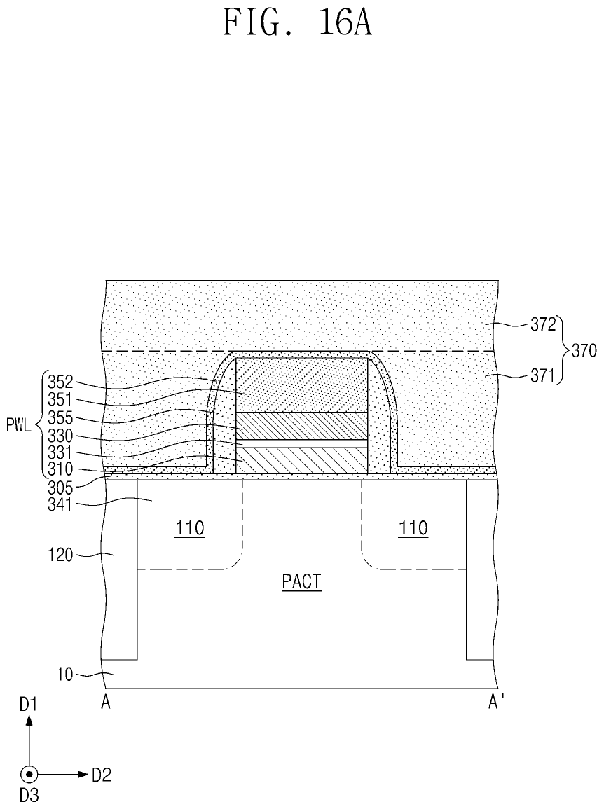

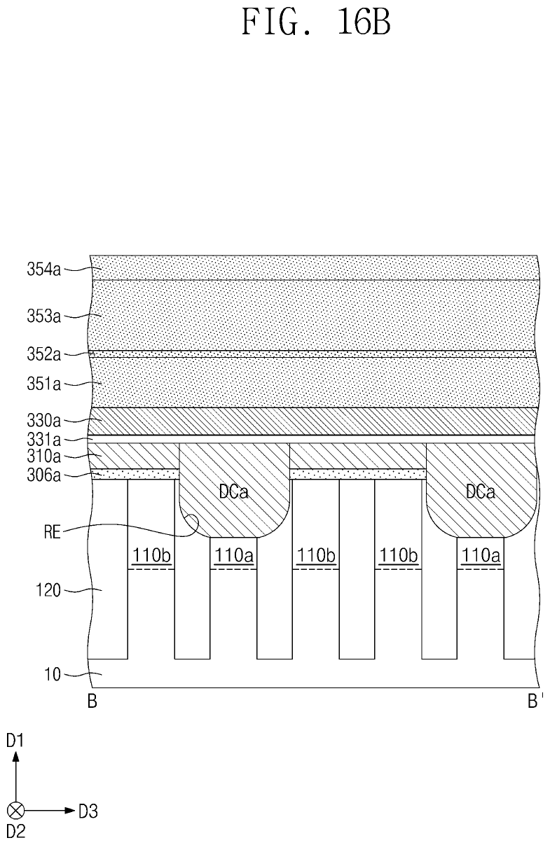

FIGS. 16A and 16B illustrate cross-sectional views respectively taken along lines A-A′ and B-B′ of FIGS. 3 and 7, showing a method of fabricating a semiconductor device according to some embodiments of the present inventive concepts.

Referring to FIGS. 16A and 16B, after the removal of the preliminary layer 372a on the cell region CR, a subsidiary capping layer 354a may further be formed on the upper capping layer 353a. The subsidiary capping layer 354a may include or may be formed of the same material as that of the upper capping layer 353a. For example, the upper capping layer 353a and the subsidiary capping layer 354a may include or may be formed of silicon oxide. The subsidiary capping layer 354a may have a top surface located at a height (or level) higher than that of the top surface of the second part 372.

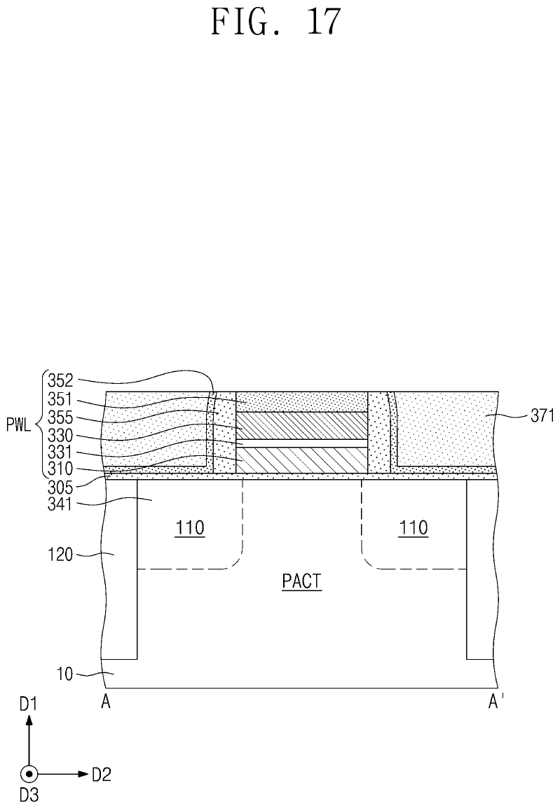

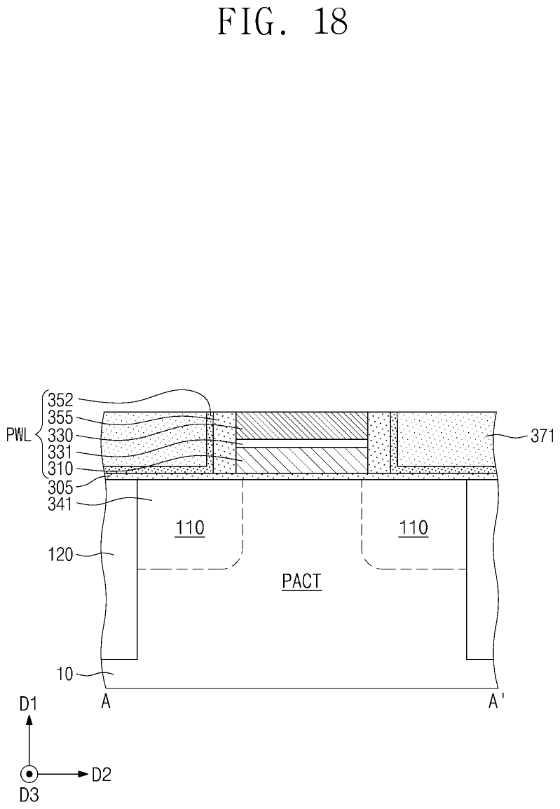

FIGS. 17 and 18 illustrate cross-sectional views taken along line A-A′ of FIG. 3, showing a method of fabricating a semiconductor device according to some embodiments of the present inventive concepts.

Referring to FIGS. 17 and 18, after the removal of the upper capping layer 353a on the peripheral region PR, at least a portion of the first lower capping pattern 351 may be further removed, and a part of an upper portion of the first part 371 may also be further removed.

For example, as shown in FIG. 17, a portion of the first lower capping pattern 351 may be removed, and a part of an upper portion of the first part 371 may be removed. Therefore, a top surface of the first lower capping pattern 351 may be exposed. Thereafter, as shown in FIG. 5, the second part 372 may be formed on a top surface of the first lower capping pattern 351, and a subsequent process may be performed.

Alternatively, as shown in FIG. 18, an entire section of the first lower capping pattern 351 may be removed, and a part of an upper portion of the first part 371 may be removed. Therefore, a top surface of the metal-containing pattern 330 may be exposed. After that, as shown in FIG. 6, the second part 372 may be formed to cover the top surface of the metal-containing pattern 330, and a subsequent process may be performed.

According to the present inventive concepts, with regard to a semiconductor device fabrication method, the upper capping layer 353a that covers the top surface of the peripheral word line PWL on the peripheral region PR may be changed into the second part 372 of the lower dielectric pattern 370. Therefore, the top surface of the peripheral word line PWL may be covered with the second part 372 of the lower dielectric pattern 370, and the second part 372 may be interposed between the contact plug CPLG and the peripheral word line PWL. The second part 372 may include or may be formed of a material whose dielectric constant is less than that of the upper cell capping pattern 353c, and therefore, there may be a reduction in electromagnetic interference between the contact plug CPLG and the peripheral word line PWL. As a result, a semiconductor device may increase in electrical properties.

In addition, the second part 372 may include or may be formed of the same material as that of the first part 371. Therefore, in an etching process for forming the through hole H, the first part 371 and the second part 372 may be etched at the substantially the same rate. Therefore, the through hole H may be formed to have a profile in which a width at an upper portion of the through hole H is the same as or greater than a width at a lower portion of the through hole H. Afterwards, because the through plug PP fills the through hole H, and because the through hole H has a width at its upper portion the same as or greater than a width at its lower portion, no void may be formed in the through plug PP formed along the profile of the through hole H. As a result, the semiconductor device may increase in electrical properties.

In addition, a material included in the first and second parts 371 and 372 may serve as a path through which a hydrogen ion moves. Therefore, when a hydrogen ion is provided to complement lattice defects of the peripheral active pattern PACT, the hydrogen ion may easily reach the peripheral active pattern PACT. In conclusion, it may be possible to complement lattice defects of the peripheral active pattern PACT and to improve reliability and electrical properties of a semiconductor device.

According to the present inventive concepts, on a peripheral region, a lower dielectric pattern covers a top surface of a peripheral word line, and may be interposed between the peripheral word line and a contact plug. The lower dielectric pattern may include or may be formed of a material whose dielectric constant is less than that of an upper cell capping pattern on a cell region, and thus there may be a reduction in electromagnetic interference between the peripheral word line and the contact plug. As a result, a semiconductor device may increase in electrical properties.

Moreover, as the lower dielectric pattern covers top and lateral surfaces of the peripheral word line, no empty void may be formed in a through plug of the contact plug formed in the lower dielectric pattern, and lattice defects in a peripheral active pattern may be easily complemented. As a result, the semiconductor device may have improved electrical properties and increased reliability.

The aforementioned description provides some embodiments for explaining the present inventive concepts. Therefore, the present inventive concepts are not limited to the embodiments described above, and it will be understood by one of ordinary skill in the art that variations in form and detail may be made therein without departing from the spirit and essential features of the present inventive concepts.

What is claimed is:

1. A semiconductor device, comprising:
a substrate;
a peripheral word line on the substrate;
a lower dielectric pattern on the substrate and covering the peripheral word line, the lower dielectric pattern including a first part that covers a lateral surface of the peripheral word line and a second part that covers a top surface of the peripheral word line;
a contact plug on one side of the peripheral word line, the contact plug penetrating the first part and the second part of the lower dielectric pattern; and
a filling pattern on the second part of the lower dielectric pattern, the filling pattern penetrating at least a portion of the second part,
wherein the contact plug includes:
a contact pad on a top surface of the lower dielectric pattern; and
a through plug that penetrates the first part and the second part of the lower dielectric pattern in a first direction perpendicular to a top surface of the substrate, the through plug being connected to the substrate,
wherein the filling pattern surrounds a lateral of the contact pad of the contact plug,
wherein the first part and the second part include the same material,
wherein the peripheral word line includes a metal-containing pattern, and
wherein the second part of the lower dielectric pattern is in direct contact with a top surface of the metal-containing pattern.

2. The semiconductor device of claim 1,
wherein the first part and the second part are connected without a boundary.

3. The semiconductor device of claim 1,
wherein the second part includes two or more materials.

4. The semiconductor device of claim 1,
wherein the second part is between a bottom surface of the contact pad and the top surface of the peripheral word line.

5. The semiconductor device of claim 1, further comprising:
a diffusion stop pattern that covers a bottom surface of the contact pad,
wherein the diffusion stop pattern is in contact with a top surface of the second part.

6. The semiconductor device of claim 1,
wherein the first part and the second part include silicon oxide.

7. The semiconductor device of claim 1,
wherein the lower dielectric pattern extends from a bottom surface of the contact pad to a lower portion of the through plug.

8. The semiconductor device of claim 1,
wherein the through plug has widths at upper and lower portions located at different heights from each other,
wherein the width at the upper portion is the same as or less than the width at the lower portion.

9. The semiconductor device of claim 1,
wherein the substrate includes a cell region and peripheral region,
wherein the peripheral word line, the lower dielectric pattern, the contact plug, and the filling pattern are on the peripheral region,
wherein the semiconductor device further comprises:
bit lines that extend along a second direction on the cell region, the second direction being parallel to the top surface of the substrate; and
an upper cell capping pattern that is on each of the bit lines and extends along the second direction along a corresponding bit line, and
wherein the second part of the lower dielectric pattern include a material whose dielectric constant is less than a dielectric constant of the upper cell capping pattern.
